(19) United States
(12) Patent Application Publication
(10) Pub. No.: US 2009/0056876 A1
(43) Pub. Date: Mar. 5, 2009

(54) Work Processing System and Plasma Generating Apparatus

(75) Inventors: Jay Joongsoo Kim, Los Altos, CA (US); Sang Hun Lee, San Ramon, CA (US); Kiyota Arai, Wakayama-shi (JP)

Correspondence Address: JORDAN AND HAMBURG LLP, 122 EAST 42ND STREET, SUITE 4000, NEW YORK, NY, 10168, US

(73) Assignees: Noritsu Koko Co., Ltd., Wakayama (JP); Amarante Technologies, Inc., Santa Clara, CA (US)

(21) Appl. No.: 12/087,082

(22) PCT Filed: Jan. 30, 2006
(86) PCT No.: PCT/US2006/003422

§ 371 Date: Aug. 14, 2008

(51) Int. Cl. C23C 16/511; C23F 1/02

(52) U.S. Cl. 156/345.41; 118/723 MW

(57) ABSTRACT

A work processing system S is provided with a plasma generating unit PU including a microwave generator 20 for generating microwaves of 2.45 GHz, a waveguide 10 for causing the microwaves to travel and a plasma generator 30 mounted on a surface of the waveguide 13 facing a work W; and a work conveyor C for conveying the work W to pass the plasma generator 30. The plasma generator 30 includes a plurality of arrayed plasma generating nozzles 31 for receiving the microwaves, generating a plasma-converted gas based on a receiving electrical energy and discharging the generated gas. The plasma-converted gas is blown to the work W in the plasma generator 30 while the work W is conveyed by the work conveyor C. It is possible both to successively plasma-process a plurality of works and to efficiently plasma-process works having large areas.

### FIELD OF THE INVENTION

The present invention relates to a work processing system capable of irradiating plasma to a work to be processed such as a substrate to clean and modify the outer surface of the work, and a plasma generating apparatus used in this work processing system.

### DESCRIPTION OF THE BACKGROUND ART

There is known a work processing system, for example, for irradiating plasma to works to be processed such as semiconductor substrates to remove organic pollutants on the outer surfaces of the works or to apply surface modification, etching, thin-film formation or thin-film removal. For example, Japanese Unexamined Patent Publication No. 2003-197397 discloses a work processing system for generating a glow discharge plasma by applying an electric field between an inner electrode and an outer electrode under atmospheric pressure using a plasma generating nozzle having the inner and outer electrodes, and blowing plasma-converted gas to fixedly arranged works. There is also known a work processing system utilizing an atmospheric pressure plasma generating apparatus that uses a microwave of, e.g., 2.45 GHz as an energy source for generating plasma.

However, the conventional work processing systems are so constructed as to blow plasma-converted gas to the outer surfaces of the works fixedly arranged in a chamber or on a work stage. Thus, a processing to the works is obliged to be a batch processing, which has presented a problem of poor operability in the case of plasma-processing a multitude of works. Further, if a work processing system is provided with a single nozzle as disclosed in Japanese Unexamined Patent Publication No. 2003-197397, there has been a problem of difficulty, for example, in processing the outer surface of a large-area substrate.

### SUMMARY OF THE INVENTION

It is an object of the present invention to provide a work processing system and a plasma generating apparatus which are free from the problems residing in the prior art.

It is another object of the present invention to provide a work processing system and a plasma generating apparatus which can continuously and efficiently apply plasma-processing to a plurality of works and a work having a large area.

According to an aspect of the invention, a work to be processed is conveyed in a specified direction, and is irradiated with plasma generated by a plasma generating apparatus. The plasma generating apparatus includes a microwave generator for generating microwaves, a waveguide for causing the microwaves to travel, and a plasma generator having a plurality of plasma generating nozzles for receiving the microwaves, generating a plasma-converted gas based on a receiving electrical energy and discharging the generated gas. The plasma generating nozzles are mounted in an array on the waveguide. The work is caused to pass the plasma generator.

These and other objects, features, aspects and advantages of the present invention will become more apparent upon a reading of the following detailed description and accompanying drawings.

### BRIEF DESCRIPTION OF THE DRAWINGS

FIG. 1 is a perspective view showing an entire construction of a work processing system according to an embodiment of the invention;

FIG. 2 is a perspective view of a plasma generating unit viewed from a direction different from the one in FIG. 1;

FIG. 3 is a side view partly in section of the work processing system;

FIG. 4 is a side view enlargedly showing two plasma generating nozzles (one plasma generating nozzle shown in an exploded manner);

FIG. 5 is a sectional view taken along the line V-V in FIG. 4;

FIG. 6 is a side view partly in section showing a plasma generating state in the plasma generating nozzle;

FIG. 7 is a perspective view showing an internal construction of a sliding short;

FIG. 8 is a top view of the plasma generating unit showing the action of a circulator;

FIG. 9 is a side view partly in section showing a disposed state of stub tuners; and

FIG. 10 is a block diagram showing a control system of the work processing system.

### DETAILED DESCRIPTION OF THE PREFERRED EMBODIMENTS OF THE INVENTION

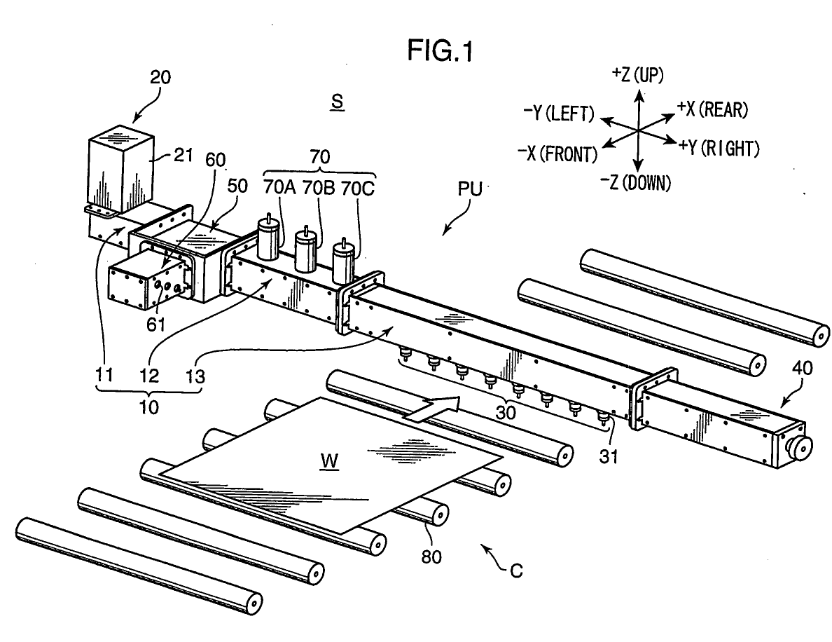

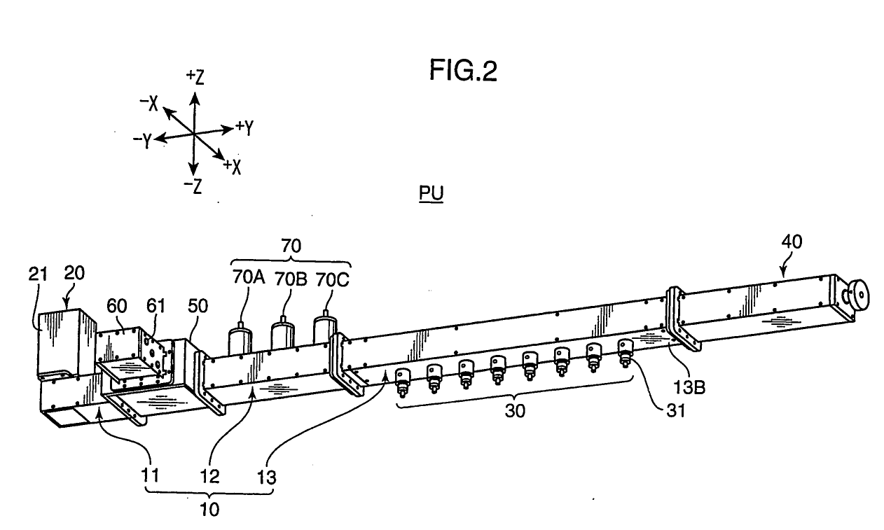

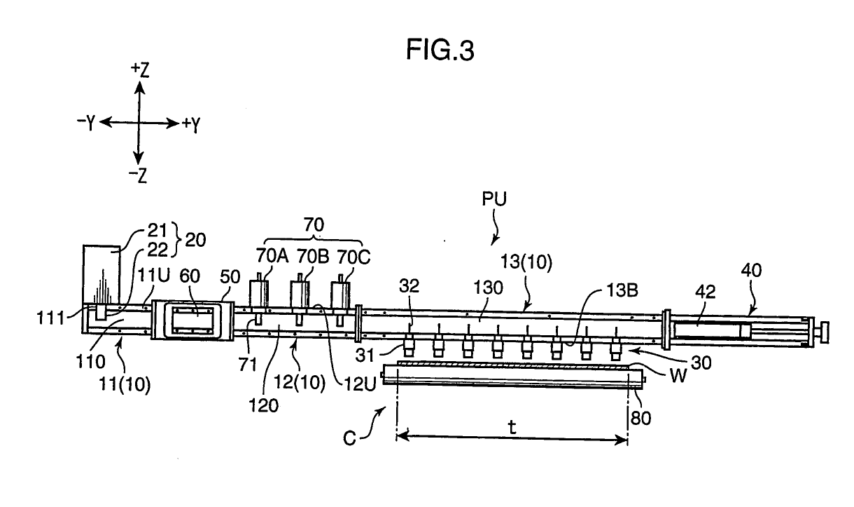

Hereinafter, one embodiment of the present invention is described in detail with reference to the accompanying drawings. FIG. 1 is a perspective view showing the entire construction of a work processing system S according to an embodiment of the present invention. This work processing system S is provided with a plasma generating unit PU (plasma generating apparatus) for generating a plasma and irradiating the generated plasma to a work W as an article to be processed, and a conveyor C for conveying the work W along a specified route by way of an irradiated area of the plasma. FIG. 2 is a perspective view of the plasma generating unit PU viewed from a direction different from the one in FIG. 1, and FIG. 3 is a side view partly in section of the work processing system S. It should be noted that, in FIGS. 1 to 3, X-X directions, Y-Y directions and Z-Z directions are respectively referred to as forward and backward directions, transverse directions and vertical directions, wherein −X direction is forward direction, +X direction backward direction, −Y leftward direction, +Y rightward direction, −Z downward direction and +Z direction upward direction.

The plasma generating unit PU is capable of generating a plasma at normal temperature and pressure using microwaves and roughly includes a waveguide 10 for causing microwaves to travel, a microwave generator 20 arranged at one end (left side) of the waveguide 10 for generating microwaves of a specified wavelength, a plasma generator 30 disposed on the waveguide 20, a sliding short 40 arranged at the other end (right side) of the waveguide 10 for reflecting the microwaves, a circulator 50 for separating the microwaves discharged into the waveguide 10 so that the reflected microwaves do not return to the microwave generator 20, a dummy load 60 for absorbing the reflected microwaves separated in the circulator 50, and a stub tuner 70 for impedance matching. The conveyor C includes conveyance rollers 80 rotated by an unillustrated driving unit. In this embodiment, the work W in the form of a flat plate is conveyed by the conveyor C.

The waveguide 10 is made of a suitable material, e.g., a nonmagnetic metal such as aluminum, assumes a long tubular shape having a rectangular cross section, and is adapted to orient the microwaves generated by the microwave generator 20 toward the plasma generator 30 and to cause the microwaves to travel along the longitudinal direction thereof. The waveguide 10 is a coupled assembly formed by coupling a plurality of waveguide parts at flange portions of the respective waveguide parts, wherein a first waveguide part 11 on which the microwave generator 20 is mounted, a second waveguide part 12 assembled with the stub tuners 70 and a third waveguide part 13 on which the plasma generator 30 is disposed are coupled one after another in this order from one end. The circulator 50 is disposed between the first and second waveguide parts 11, 12, and the sliding short 40 is coupled to the other end of the third waveguide part 13.

Each of the first to third waveguide parts 11, 12, 13 is assembled into a rectangular tube using a top plate, a bottom plate and two side plates that are all metal flat plates, and has the flange plates mounted at the opposite ends thereof. Instead of assembling such flat plates into the waveguide parts, rectangular waveguide parts formed by extrusion or bending a plate material or an undivided waveguide may be used. The cross section of the waveguide is not limited to a rectangular shape, and a waveguide having an elliptic cross section may, for example, be used. Further, the material for the waveguide 10 is not limited to the nonmagnetic metal, but the waveguide 10 may be made of other various material having the function of guiding waves.

The microwave generator 20 includes a generator main body 21 having a microwave generation source such as a magnetron for generating microwaves of, e.g., 2.45 GHz and an amplifier for adjusting the intensity of the microwaves generated by the microwave generation source to a specified output intensity, and a microwave transmitting antenna 22 for transmitting the microwaves generated in the generator main body 21 to the inside of the waveguide 10. In the plasma generating unit PU according to this embodiment, the microwave generator 20 of the continuous variable type capable of outputting a microwave energy of, e.g., 1 W to 3 kW is preferably used.

As shown in FIG. 3, the microwave generator 20 is such that the microwave transmitting antenna 22 projects from the generator main body 21, and is fixedly placed on the first waveguide part 11. More specifically, the microwave generator 20 is fixed such that the generator main body 21 is placed on a top plate 11U of the first waveguide part 11 and the microwave transmitting antenna 22 is introduced through a through hole 111 formed in the top plate 11U to project into a waveguide space 110 in the first waveguide part 11. By constructing the microwave generator 20 as above, the microwaves of, e.g., 2.45 GHz transmitted from the microwave transmitting antenna 22 are caused by the waveguide 10 to travel from one end (left side) to the other end (right side) of the waveguide 10.

The plasma generator 30 includes eight plasma generating nozzles 31 projecting from a bottom plate 13B (one side surface of the rectangular waveguide; surface facing the work to be processed) of the third waveguide part 13 while being arrayed in a transverse row. The width of the plasma generator 30, i.e., the width of the transverse row of the eight plasma generating nozzles 31 substantially coincides with width “t” of the work W in the form of a flat plate orthogonal to a conveying direction. Thus, the entire outer surface (surface facing the bottom plate 13B) of the work W can be plasma-processed while the work W is conveyed by the conveyance rollers 80. It should be noted to be preferable that the array interval between the eight plasma generating nozzles 31 is determined in accordance with a wavelength λG of the microwave traveling in the waveguide 10. For example, it may be preferable to arrange plasma generating nozzles 31 at a pitch of a half of the wavelength λG or a quarter of wavelength λG. In the case of using the microwave of 2.45 GHz, plasma generating nozzles 31 are arranged at a pitch of 115 mm (λG/2) or 57.5 mm (λG/4) because of its wavelength λG being 230 mm.

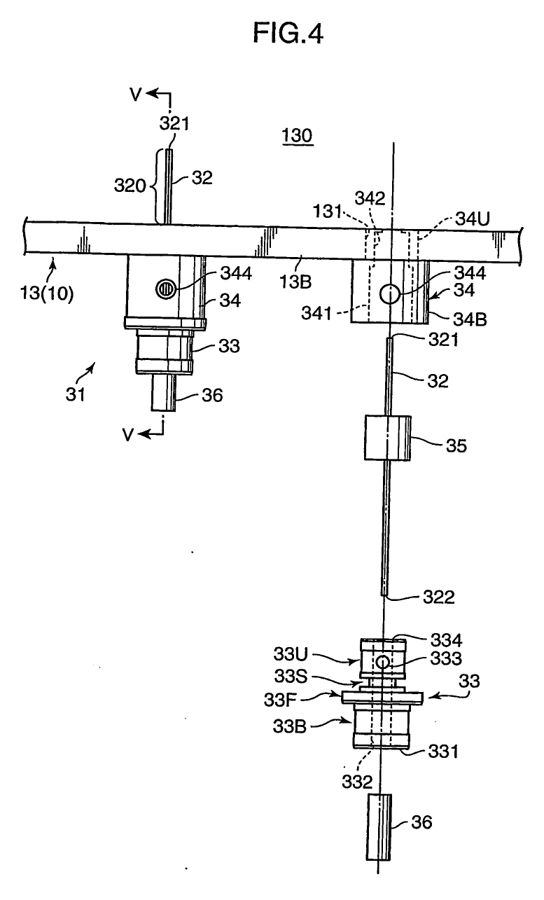

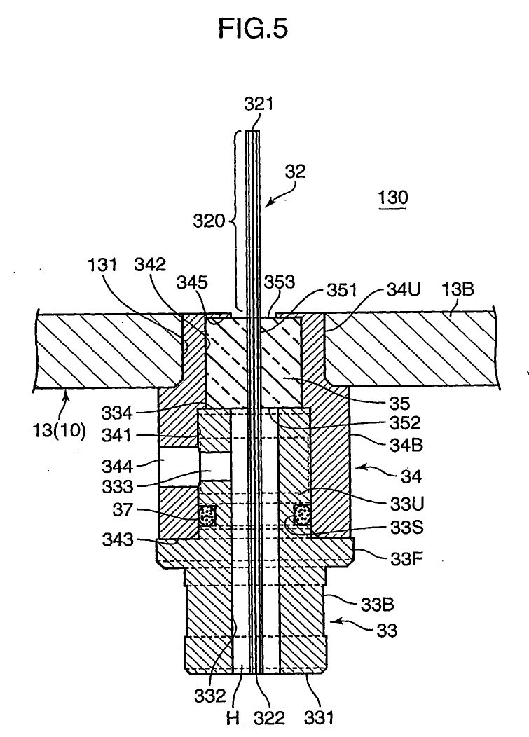

FIG. 4 is a side view enlargedly showing two plasma generating nozzles 31 (one plasma generating nozzle 31 is shown in an exploded manner), and FIG. 5 is a sectional view taken along the line V-V in FIG. 4. The plasma generating nozzle 31 includes a core conductor (inner conductor) 32, a nozzle main body (outer conductor) 33, a nozzle holder 34, a sealing member 35 and a protection tube 36.

The core conductor 32 is a bar-shaped member made of a metal having a good electrical conduction property, and is vertically arranged such that an upper end portion 321 thereof penetrates through the bottom plate 13B of the third waveguide part 13 to project into a waveguide space 130 by a specified length (this projecting portion is referred to as a receiving antenna portion 320), a bottom end 322 thereof is substantially in flush with a bottom edge 331 of the nozzle main body 33. Microwave energy (microwave power) is imparted to the core conductor 32 by the receiving antenna portion 320 receiving the microwaves traveling in the waveguide 10. This core conductor 32 is held by the sealing member 35 at a substantially longitudinal middle position thereof.

The nozzle main body 33 is a tubular member made of a metal having a good electrical conduction property and including a tubular space 332 for accommodating the core conductor 32. The nozzle holder 34 is also a tubular member made of a metal having a good electrical conduction property and including a lower holding space 341 of a relatively larger diameter for holding the nozzle main body 33 and an upper holding space 342 of a relatively smaller diameter for holding the sealing member 35. On the other hand, the sealing member 35 is a tubular member made of an insulating material such as Teflon (product name of DuPont) or a like heat resistant resin material or a ceramic, and having a holding hole 351 for fixedly holding the core conductor 32 along its center axis.

The nozzle main body 33 includes an upper trunk portion 33U to be fitted into the lower holding space 341 of the nozzle holder 34, an annular recess 33S for holding a gas sealing ring 37 to be described later, a ring-shaped flange portion 33F and a lower trunk portion 33B projecting from the nozzle holder 34 in this order from the top. The upper trunk portion 33U is formed with a communication hole 333 for supplying a specified processing gas to the tubular space 332.

The nozzle main body 33 functions as an outer conductor arranged around the core conductor 32, and is introduced on a center axis of the tubular space 332 while ensuring a specified annular space H (insulation spacing) around. The nozzle main body 33 is fitted into the nozzle holder 34 such that the outer circumferential surface of the upper trunk portion 33U is in contact with the inner circumferential wall of the lower holding space 341 of the nozzle holder 34 and the upper end surface of the flange portion 33F is in contact with a bottom end 343 of the nozzle holder 34. It is desirable to detachably mount the nozzle main body 33 in the nozzle holder 34 by a fixing construction using a plunger, a set screw and the like.

The nozzle holder 34 includes an upper trunk portion 34U (substantially corresponding to the position of the upper holding space 342) to be closely fitted into a through hole 131 formed in the bottom plate 13B of the third waveguide part 13 and a lower trunk portion 34B (substantially corresponding to the position of the lower holding space 341) extending downward from the bottom plate 13B. A gas supplying hole 344 for supplying the processing gas to the annular space H is formed in the outer circumferential surface of the lower trunk portion 34B. Although not shown, a tube fitting or the like is mounted at the gas supplying hole 344 for the connection with an end of a gas supplying tube for supplying the specified processing gas. The gas supplying hole 344 and the communication hole 333 of the nozzle main body 33 have the positions thereof so set as to communicate with each other when the nozzle main body 33 is fitted to a specified position into the nozzle holder 34. It should be noted that the gas sealing ring 37 is provided between the nozzle main body 33 and the nozzle holder 34 in order to suppress the gas leakage through a portion where the gas supplying hole 344 and the communication hole 333 abut on each other.

The sealing member 35 is held in the upper holding space 342 of the nozzle holder 34 such that a bottom end 352 thereof is in contact with an upper end 334 of the nozzle main body 33 and an upper end 353 thereof is in contact with an upper-end locking portion 345 of the nozzle holder 34. In other words, the sealing member 35 supporting the core conductor 32 is fitted into the upper holding space 342 such that the bottom end 352 is pushed by the upper end 334 of the nozzle main body 33.

The protection tube 36 (not shown in FIG. 5) is made of a quartz glass pipe of a specified length and has an outer diameter substantially equal to the inner diameter of the tubular space 332 of the nozzle main body 33. This protection tube 36 is fitted into the tubular space 332 such that part thereof projects from the bottom end 331 of the nozzle main body 33 in order to improve the corrosion resistance of the bottom end 331 of the nozzle main body 33. The protection tube 36 may be fitted into the tubular space 332 such that the end of the protection tube 36 becomes flush with the bottom end 331 of the nozzle main body 33, or the protection tube 36 is entirely within the tubular space 332.

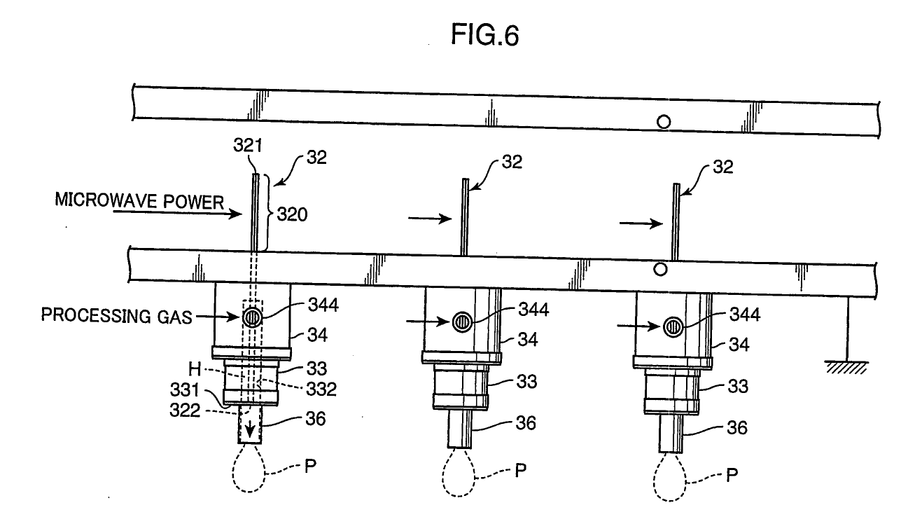

As a result of constructing the plasma generating nozzle 31 as above, the nozzle main body 33, the nozzle holder 34 and the third waveguide part 13 (waveguide 10) are electrically conductive to each other (at the same potential), whereas the core conductor 32 is electrically insulated from these members by being supported by the insulating sealing member 35. Accordingly, if the microwaves are received by the receiving antenna portion 320 of the core conductors 32 to supply the microwave power to the core conductors 32 with the waveguide 10 grounded as shown in FIG. 6, an electric-field concentrating portion is formed in the proximity of the bottom end 322 and the bottom end 331 of the nozzle main body 33.

When an oxygen-containing processing gas such as an oxygen gas or air is supplied into the annular space H through the gas supplying hole 344 in this state, the processing gas is excited by the microwave power to generate a plasma (ionized gas) near bottom ends 322 of the core conductors 32. This plasma is a reactive plasma whose electron temperature is about tens of thousands degrees, but whose gas temperature is approximate to ambient temperature (plasma whose electron temperature indicated by electrons is extremely high as compared to gas temperature indicated by neutral molecules), and which is generated under atmospheric pressure.

The processing gas plasma-converted as above is discharged from the bottom ends 331 of the nozzle main bodies 33 as plumes P by gas flows given through the gas supplying holes 344. The plumes P contain radicals, and oxygen radicals are generated if the oxygen-containing gas is used, for example, as the processing gas, whereby the plumes P come to possess a function of dissolving and removing organic matters and a function of removing resists. Since a plurality of plasma generating nozzles 31 are arranged in the plasma generating unit PU of this embodiment, the plumes P linearly arranged in transverse direction can be generated.

If an inert gas, such as an argon gas, or a nitrogen gas is used as the processing gas, the outer surfaces of various kinds of substrates can be cleaned and modified. Further, if a compound gas containing fluorine is used, the outer surface of the substrate can be modified into a water repellant surface. If a compound gas containing hydrophilic groups is used, the outer surface of the substrate can be modified into a hydrophilic surface. Furthermore, if a compound gas containing metallic elements is used, a metallic thin film can be formed on the substrate.

The sliding short 40 is provided to optimize the coupled state of the core conductors 32 of the respective plasma generating nozzles 31 and the microwaves traveling in the waveguide 10, and is coupled to the right end of the third waveguide part 13 in order to make a standing-wave pattern adjustable by changing the reflected position of the microwaves. Accordingly, if no standing waves are utilized, a dummy load having an action of absorbing electromagnetic waves is mounted in place of the sliding short 40.

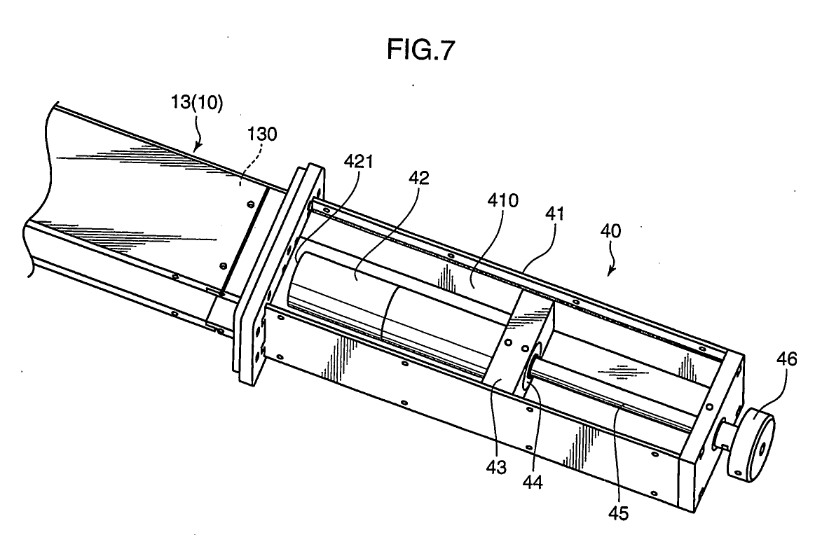

FIG. 7 is a perspective view showing an external construction of the sliding short 40. As shown in FIG. 7, the sliding short 40 has a container structure having a rectangular cross section similar to the waveguide 10, and includes a container 41 made of the same material as the waveguide 10 and having a hollow space 410, a cylindrical reflecting block 42 accommodated in the hollow space 410, a rectangular block 43 integrally attached to the base end of the reflecting block 42 and slidable along transverse directions in the hollow space 410, a moving mechanism 44 assembled into the rectangular block 43, and an adjusting knob 46 coupled to the reflecting block 42 via a shaft 45.

The reflecting block 42 is a cylindrical body extending in transverse direction so that a leading end surface 421 as a reflecting surface for microwaves faces the waveguide space 130 of the third waveguide part 13. The reflecting block 42 may be made to have a prismatic body as the rectangular block 43. The moving mechanism 44 serves as a mechanism for allowing the rectangular block 43 and the reflecting block 42 integral with the rectangular block 43 to move along the transverse directions in accordance with rotation of the adjusting knob 46. Rotating the adjusting knob 46 causes the reflecting block 42 to move along the transverse directions in the hollow space 410 while being guided by the rectangular block 43. The position of the leading end surface 421 of the reflecting block 42 is adjusted by moving the reflecting block 42 to optimize the standing-wave pattern. It is preferable to automate the rotating operation of the adjusting knob 46 using a stepping motor or the like.

The circulator 50 is, for example, a three-port circulator of the waveguide type having a built-in ferrite column, and adapted to let the reflected microwaves returning without being consumed in the plasma generator 30 travel toward the dummy load 60 out of the microwaves caused to travel toward the plasma generator 30, but not returning the reflected microwaves to the microwave generator 20. The arrangement of such a circulator 50 prevents the microwave generator 20 from being overheated by the reflected microwaves.

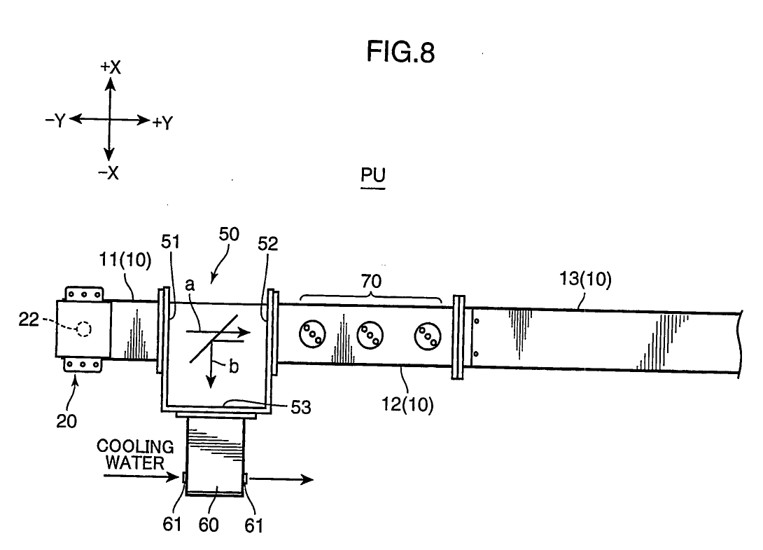

FIG. 8 is a top view of the plasma generating unit PU showing the action of the circulator 50. As shown in FIG. 8, the first waveguide part 11 is connected with a first port 51 of the circulator 50; the second waveguide part 12 with a second port 52; and the dummy load 60 with a third port 53. The microwaves generated from the microwave transmitting antenna 22 of the microwave generator 20 travel to the second waveguide 12 by way of the first port 51 and the second port 52 as indicated by an arrow “a”. On the other hand, the reflected microwaves traveling from the second waveguide part 12 through the second port 52 are deflected toward the third port 53 to enter the dummy load 60.

The dummy load 60 is a water-cooled (may also be air-cooled) electromagnetic wave absorbing body for absorbing the aforementioned reflected microwaves and converting them into heat. This dummy load 60 is provided with a cooling-water passage through which cooling water runs, so that the heat generated by thermally converting the reflected microwaves is heat-exchanged with the cooling water.

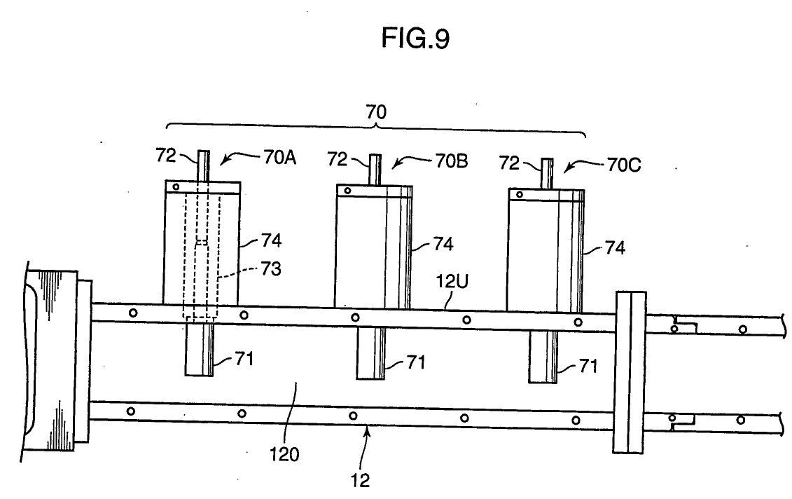

The stub tuner 70 is for matching the impedances of the core conductors 32 of the plasma generating nozzles 31 as loads, and includes three stub tuner units 70A to 70C arranged in series at specified intervals on a top plate 12U of the second waveguide part 12. FIG. 9 is a side view partly in section showing the disposed state of the stub tuner 70. As shown in FIG. 9, the three stub tuner units 70A to 70C have an identical construction comprised of a stub 71 positioned within the waveguide space 120 of the second waveguide part 12, an operating bar 72 directly coupled to the stub 71, a moving mechanism 73 for moving the stub 71 upward and downward so as to retract and project, and a coat 74 for holding the stub 71, the operating bar 72 and the moving mechanism 73.

A projecting length of the stub 71 provided in each of the stub tuner units 70A to 70C into the waveguide space 120 is independently adjustable by the corresponding operating bar 72. The projecting lengths of the stubs 71 are determined, for example, by searching for points where the power consumptions by the core conductors 32 are peaked (points where the reflected microwaves are at the minimum) while monitoring the microwave power. Such impedance matching is linked with the movement of the sliding short 40 if necessary. It is also desirable to automate the operation of the stub tuner 70 using a stepping motor or the like.

The conveyor C includes a plurality of conveyance rollers 80 arranged along a specified conveyance path and conveys the work W to be processed by way of the plasma generator 30 by driving the conveyance rollers 80 by means of the unillustrated driving unit. The work W to be processed may be illustrated as a flat substrate such as a plasma display panel or a semiconductor substrate or a circuit board having an electronic component mounted thereon. Parts, assembled parts and the like that are not flat can also be processed. In such a case, a belt conveyor or the like may be adopted in place of the conveyance rollers.

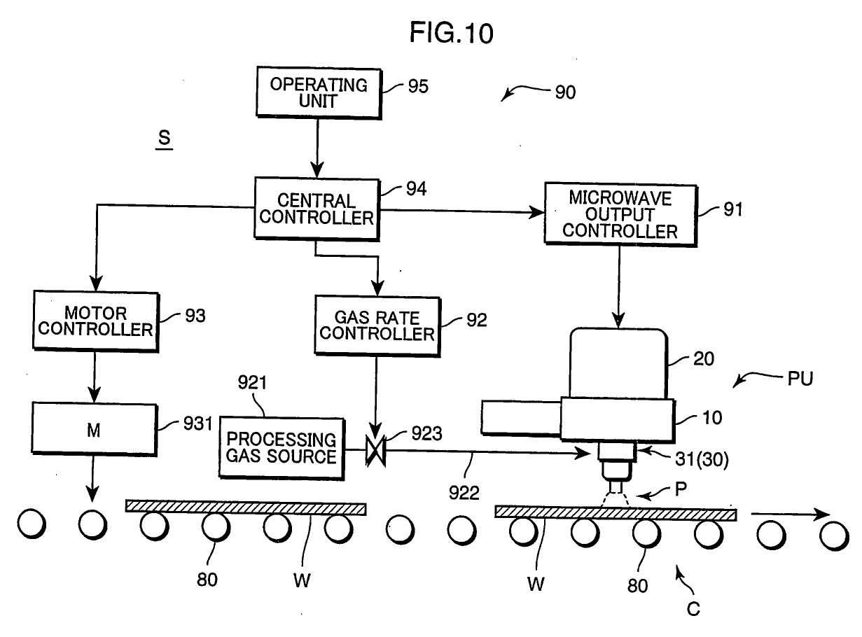

Next, the electrical construction of the work processing system S according to this embodiment is described. FIG. 10 is a block diagram showing a control system 90 of the work processing system S. This control system 90 is a CPU (central processing unit) or the like and is functionally provided with a microwave output controller 91, a gas flow rate controller 92, a motor controller 93 and a central controller 94. Further, an operating unit 95 is provided to give specified operation signals to the central controller 94.

The microwave output controller 91 is for on-off controlling the microwaves outputted from the microwave generator 20 and controlling the output intensities of the microwaves, and controls a microwave generating operation by the generator main body 21 of the microwave generator 20 by generating specified pulse signals.

The gas flow rate controller 92 is for controlling the flow rate of the processing gas supplied to the respective plasma generating nozzles 31 of the plasma generator 30. Specifically, the gas flow rate controller 92 controls the opening and closing of flow rate control valves 923 provided in gas supplying pipes 922 connecting a processing gas source 921 such as a gas cylinder and the plasma generating nozzles 31 or adjusts a degree of opening.

The motor controller 93 controls the operation of a drive motor 931 for driving the conveyance rollers 80 to start and stop the conveyance of the work W and control a conveying speed.

The central controller 94 governs an overall operation control of the work processing system S, and controls the operations of the microwave output controller 91, the gas flow rate controller 92 and the motor controller 93 based on a specified sequence in response to an operation signal given from the operation unit 95. Specifically, in accordance with a control program given beforehand, the central controller 94 causes the conveyance of the work W to be started to bring the work W to the plasma generator 30, and causes plasmas (plumes P) to be generated by giving the microwave power while supplying the processing gas of a specified flow rate to the respective plasma generating nozzles 31, whereby the plumes P are blown onto the outer surface of the work W being conveyed. In this way, a plurality of works W can be successively processed.

According to the work processing system S described above, the plasma-converted gas can be blown onto the work W from a plurality of plasma generating nozzles 31 mounted in an array on the waveguide 13 while the work W is conveyed by the conveyor C. Thus, it is possible both to successively plasma-process a plurality of works W and to efficiently plasma-process works having large areas. Accordingly, it is possible to provide the work processing system S or the plasma generating apparatus PU having a better operability in plasma-processing various kinds of works as compared to conventional work processing systems of the batch processing type. Further, since plasma can be generated at ambient temperature and pressure, the installation can be simplified without necessitating a vacuum chamber and the like.

Further, the microwaves generated by the microwave generator 20 are received by the core conductors 32 of the respective plasma generating nozzles 31 and the plasma-converted gas can be discharged from the respective plasma generating nozzles 31 based on the received electrical energy. Thus, a transmission system for transmitting the energy of the microwaves to the respective plasma generating nozzles 31 can be simplified. Therefore, the system can have a simpler construction and a reduced production cost.

Furthermore, since the plasma generator 30 having a plurality of plasma generating nozzles 31 arrayed in a row has a width substantially equal to the width of the work W in the form of a flat plate orthogonal to the conveying direction, the entire surface of the work W can be completely processed merely by letting the work W pass the plasma generator 30 only once by means of the conveyor C, thereby remarkably improving efficiency in plasma-processing the work W in the form of a flat plate. Further, the plasma-converted gas can be blown at the same timing to the work W conveyed to the plasma generator 30, thereby enabling a uniform surface processing and the like.

Although the work processing system S according to one embodiment of the present invention is described, the present invention is not limited thereto and may be embodied as follows.

(1) Although a plurality of plasma generating nozzles 31 are arrayed in a row in the foregoing embodiment, the nozzle array may be suitably determined depending on the shape of works, the intensity of the microwave power and other factors. For example, a plurality of plasma generating nozzles 31 may be arrayed in a matrix by arranging a plurality of rows of plasma generating nozzles 31 along the conveying direction of the works or may be arrayed in an offset arrangement.

(2) Although the work W in the form of a flat plates are conveyed while being placed on the conveyance rollers 80 as the conveyor C in the foregoing embodiment, the work may be conveyed to the plasma generator 30 while being nipped between upper and lower conveyance rollers; while being contained in a specified basket or the like conveyed by means of a line conveyor or the like without using the conveyance rollers; or while being gripped by a robot hand or the like.

(3) Although the magnetron for generating the microwaves of 2.45 GHz is shown as the microwave generating source in the foregoing embodiment, various high-frequency power sources other than magnetrons are also usable as such. Further, microwaves having wavelengths different from 2.45 GHz may be used.

(4) It is desirable to dispose a power meter at a specified position of the waveguide 10 in order to measure the microwave power in the waveguide 10. For example, in order to grasp a ratio of the reflected microwave power to the microwave power discharged from the microwave transmitting antenna 22 of the microwave generator 20, a waveguide having a built-in power meter may be provided between the circulator 50 and the second waveguide part 12.

As described above, a novel work processing system is adapted for irradiating plasma to a work to apply a specified processing to the work while conveying the work. The work processing system comprises a plasma generating apparatus including a microwave generator for generating microwaves, a waveguide for causing the microwaves to travel, and a plasma generator having a plurality of plasma generating nozzles for receiving the microwaves, generating a plasma-converted gas based on a receiving electrical energy and discharging the generated gas, the plasma generating nozzles being mounted in an array on the waveguide; and a work conveyor for conveying the work to pass the plasma generator.

With this construction, the outer surfaces of the works can be successively processed by discharging the plasma-converted gas to the works from the plasma generating nozzles mounted on the waveguide while conveying the works by the work conveyor. Further, since the plurality of plasma generating nozzles are mounted in an array on the waveguide, works having large areas can also be dealt with. Therefore, it is possible to provide a work processing system or a plasma generating apparatus having a good operability in plasma-processing various kinds of works.

Preferably, each plasma generating nozzle may include an inner conductor having one end positioned within the waveguide, an outer conductor arranged around the inner conductor while being spaced from the inner conductor, and a gas supplying portion for supplying a specified gas to a gap between the inner conductor and the outer conductor, whereby discharging the plasma-converted gas from the leading end thereof.

With this construction, the microwaves traveling in the waveguide are received by the projecting portion of the inner conductor within the waveguide, and the received microwave energy is given to the inner conductors. Plasma can be generated by forming a high electric-field portion between the outer conductor and the inner conductor utilizing such an energy. Accordingly, the plasma-converted gas can be discharged from the leading ends of the nozzles by supplying the specified gas to the gap between the inner conductor and the outer conductor from the gas supplying portion.

The microwaves generated by the microwave generator are received by the inner conductors of the respective plasma generating nozzles and the plasma-converted gas is discharged from the respective plasma generating nozzles based on the received electrical energy. Thus, a transmission system for the energy of the microwaves to the respective plasma generating nozzles can be simplified. Therefore, there are advantages of simplifying the construction of the system and reducing a production cost.

Preferably, the work conveyor may be constructed to be able to convey the work in the form of a flat plate, and the plasma generator has a width substantially equal to that of the work orthogonal to a conveying direction. With this construction, the entire surface of a wide work such as a flat substrate can be completely processed merely by causing the work to pass the plasma generator only once by means of the conveyor. Thus, efficiency in plasma-processing wide works can be remarkably improved.

In such a case, the waveguide may be preferably a rectangular waveguide, and the plurality of plasma generating nozzles are arrayed in a row on one side surface of the rectangular waveguide. With this construction, the plasma-converted gas can be discharged at the same timing to the work being conveyed, thereby enabling a uniform surface processing and the like. Therefore, it is possible not only to improve efficiency in plasma-processing wide works, but also to uniformly process the wide works.

Also, a novel plasma generating apparatus comprises a microwave generator for generating microwaves; a waveguide for causing the microwaves to travel; and a plasma generator having a plurality of plasma generating nozzles for receiving the microwaves, generating a plasma-converted gas based on a received electrical energy and discharging the generated gas, the plasma generating nozzles being mounted in an array on the waveguide. The waveguide has a surface facing a conveyance path for a work to be processed. The plasma generator is mounted on the facing surface.

In this plasma generating apparatus, it may be preferable that each plasma generating nozzle includes a inner conductor having one end positioned within the waveguide, an outer conductor arranged around the inner conductor while being spaced from the inner conductor, and a gas supplying portion for supplying a specified gas to a gap between the inner conductor and the outer conductor, whereby discharging the plasma-converted gas from the leading end thereof.

The work processing system and the plasma generating apparatus are suitably applicable to etching systems and film forming systems for semiconductor substrates such as semiconductor wafers, cleaning systems for glass substrates such as plasma display panels or printed circuit boards, sterilizing systems for medical equipment, protein degradation systems and the like.

As this invention may be embodied in several forms without departing from the spirit of essential characteristics thereof, the present embodiment is therefore illustrative and not restrictive, since the scope of the invention is defined by the appended claims rather than by the description preceding them, and all changes that fall within metes and bounds of the claims, or equivalence of such metes and bounds are therefore intended to embraced by the claims.

What is claimed is:

1. A work processing system for irradiating plasma to a work to apply a specified processing to the work while conveying the work, comprising:
a plasma generating apparatus including a microwave generator for generating microwaves, a waveguide for causing the microwaves to travel, and a plasma generator having a plurality of plasma generating nozzles for receiving the microwaves, generating a plasma-converted gas based on a receiving microwave energy and discharging the generated gas, the plasma generating nozzles being mounted in an array on the waveguide; and
a work conveyor for conveying the work to pass the plasma generator.

2. A work processing system according to claim 1, wherein each plasma generating nozzle includes an inner conductor having one end positioned within the waveguide, an outer conductor arranged around the inner conductor while being spaced from the inner conductor, and a gas supplying portion for supplying a specified gas to a gap between the inner conductor and the outer conductor, whereby discharging the plasma-converted gas from the leading end thereof.

3. A work processing system according to claim 2, wherein the work conveyor is constructed to be able to convey the work in the form of a flat plate, and the plasma generator has a width substantially equal to that of the work orthogonal to a conveying direction.

4. A work processing system according to claim 3, wherein the waveguide is a rectangular waveguide, and the plurality of plasma generating nozzles are arrayed in a row on one side surface of the rectangular waveguide.

5. A work processing system according to claim 1, wherein the work conveyor is constructed to be able to convey the work in the form of a flat plate, and the plasma generator has a width substantially equal to that of the work orthogonal to a conveying direction.

6. A plasma generating apparatus, comprising:
a microwave generator for generating microwaves;
a waveguide for causing the microwaves to travel; and
a plasma generator having a plurality of plasma generating nozzles for receiving the microwaves, generating a plasma-converted gas based on a received microwave energy and discharging the generated gas, the plasma generating nozzles being mounted in an array on the waveguide,
wherein the waveguide has a surface facing a conveyance path for a work to be processed, and the plasma generator is mounted on the facing surface.

7. A plasma generating apparatus according to claim 6, wherein each plasma generating nozzle includes an inner conductor having one end positioned within the waveguide, an outer conductor arranged around the inner conductor while being spaced from the inner conductor, and a gas supplying portion for supplying a specified gas to a gap between the inner conductor and the outer conductor, whereby discharging the plasma-converted gas from the leading end thereof.
